(19) United States
(12) Patent Application Publication
(10) Pub. No.: US 2026/0324089 A1
(43) Pub. Date: Oct. 15, 2026

(54) SEMICONDUCTOR DEVICE WITH SEMICONDUCTOR THERMAL STRUCTURE

(71) Applicant: GlobalFoundries Singapore Pte. Ltd., Singapore (SG)

(72) Inventor: Aung Kyaw WIN, Singapore (SG)

(21) Appl. No.: 19/179,939

(22) Filed: Apr. 15, 2025

(51) Int. Cl. H10D 88/00; H10D 86/00; H10W 10/20; H10W 40/20

(52) U.S. Cl. CPC H10D 88/00; H10D 86/201; H10W 10/20; H10W 40/233

(57) ABSTRACT

A semiconductor device includes a first slate including a first active device over a dielectric layer. A second slate is bonded to the first slate, the second slate including a substrate including a base semiconductor layer, a dielectric layer over the base semiconductor layer, and an active semiconductor layer over the dielectric layer. A first thermal structure is over the first active device for dissipating heat generated by the first active device, the first thermal structure including a semiconductor material.

### BACKGROUND

The semiconductor industry continues to improve the integration density of electronic components by various techniques, including reducing the minimum feature size of devices and using devices with vertical orientations. Another technique is to bond two stacked substrates to one another to form a three-dimensional integrated circuit (3DIC). 3DICs can be formed by bonding a wafer to another wafer, bonding a die to a wafer, or bonding a die to another die. 3DIC bonding can be performed by fusing metal bumps on the bonding surfaces as an interconnect scheme, or by hybrid bonding in which opposing substrate surfaces are placed against one another and heated so that both dielectric-to-dielectric and direct metal-to-metal bonds are formed between the two surfaces.

Self heating effect is an important issue in 3D integrated circuits (3DICs), including 3D RF devices, due to their inherently high-power density and complex multi-layered architecture. The vertical stacking of multiple functional layers in 3DICs generates significant heat during operation. If the heat is not effectively dissipated, it can lead to increased operating temperatures, which negatively impact the performance of the device. Adverse effects may include shifts in threshold voltage, reduced carrier mobility, increased leakage currents, RF performance in RF devices, and potential thermal-induced failure, ultimately compromising the reliability and efficiency of the 3DIC. Therefore, implementing an effective thermal management solution would be desirable to ensure the optimal performance, stability, and longevity of these advanced semiconductor devices.

### SUMMARY

Embodiments of the present disclosure relate to a bonded semiconductor device with a semiconductor thermal structure to dissipate heat generated by a top active device.

In an embodiment, a semiconductor device includes a first slate including a first active device over a dielectric layer. A second slate is bonded to the first slate, the second slate including a substrate including a base semiconductor layer, a dielectric layer over the base semiconductor layer, and an active semiconductor layer over the dielectric layer. A first thermal structure is over the first active device for dissipating heat generated by the first active device, the first thermal structure including a semiconductor material.

In an embodiment, a three-dimensional integrated circuit (3DIC) includes a bottom slate including a silicon-on-insulator (SOI) substrate and a bottom active device. A top slate joins to the bottom slate and includes a first top active device. A dielectric layer is over the first top active device. A first thermal structure is over the first top active device for dissipating heat generated by the first top active device, the first thermal structure including a semiconductor material.

In an embodiment, a method for making a semiconductor device includes providing a bottom slate including a bottom silicon-on-insulator (SOI) substrate, the bottom SOI substrate including a bottom active device; providing a top slate having a top SOI substrate including a top active device; bonding the first slate and the second slate; forming a semiconductor thermal structure using a base silicon layer of the top SOI substrate, the semiconductor thermal structure being configured to dissipate heat generated by the top active device; forming a layer over the semiconductor thermal structure; and forming a top electrode over the layer provided over the semiconductor thermal structure.

### BRIEF DESCRIPTION OF THE DRAWINGS

FIG. 1 illustrates a semiconductor device with a top semiconductor substrate bonded to a bottom semiconductor substrate according to an embodiment of the present disclosure.

FIGS. 2A-2H illustrate a method for fabricating a three-dimensional (3D) semiconductor device (e.g., RF device) according to an embodiment of the present disclosure.

### DETAILED DESCRIPTION

Embodiments of the present disclosure relate to a bonded semiconductor device with an improved self-heating effect. In particular, embodiments relate to a bonded semiconductor device or a three-dimensional integrated circuit (3DIC) such as a 3D integrated RF device that has a semiconductor thermal structure that dissipates heat generated by a top active device.

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured. The figures are not drawn to scale, and features may be enlarged or diminished for visual clarity.

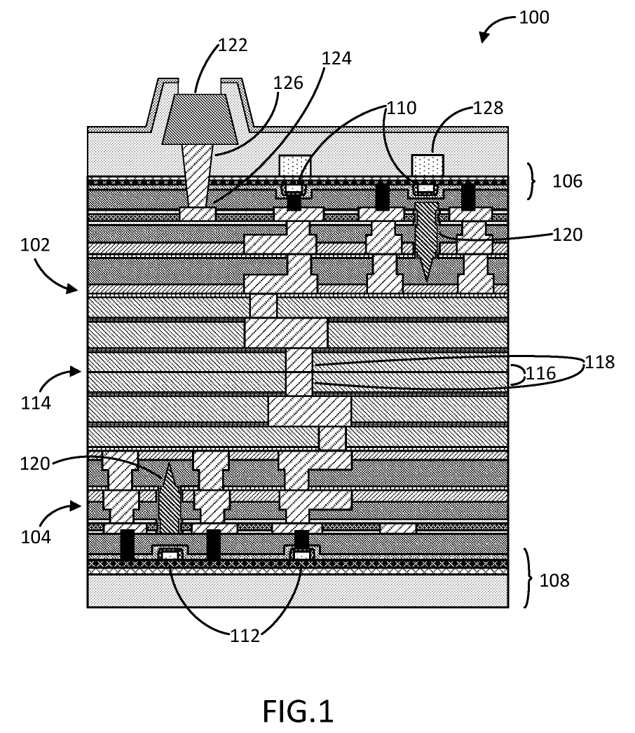

FIG. 1 illustrates an embodiment of a semiconductor device 100 with a first semiconductor slate 102 (e.g., top slate) bonded to a second semiconductor slate 104 (e.g., bottom slate). The semiconductor device 100 may be a three-dimensional integrated circuit (3DIC) such as a three-dimensional (3D) RF device. In an embodiment, the first and second semiconductor slates include first and second silicon-on-insulator (SOI) substrates 106 and 108, respectively. The use of SOI technology helps reduce parasitic capacitance, provides high isolation, and minimize power loss, which are beneficial for optimizing RF performance.

The top slate 102 includes a plurality of top active devices 110. In an embodiment, the top active device is an RF component, such as a high-speed transistor or other active circuitry for signal processing, filtering or power management. The bottom slate 104 similarly hosts a plurality of bottom active devices 112, which may serve complementary functions, such as signal processing, filtering, or power management.

A bonding interface (or bonding fabric )114 joins the first slate 102 to the second slate 104 to provide vertical integration of the top and bottom active devices. In an embodiment, the bonding fabric 114 includes an interlayer dielectric layer (e.g., an oxide) 116 and a metal 118, providing mechanical stability and electrical continuity between the layers. In an embodiment, the interlayer dielectric layer 116 may comprise an oxide including silicon. For example, interlayer dielectric layer 116 may be formed using a tetraethyl orthosilicate (TEOS) material. However, embodiments are not limited to this particular bonding technique. The first slate 102 may be face bonded to the second slate 104 using various bonding methods, such as, directing bonding, hybrid bonding, or others.

Air gaps 120 are introduced between specific regions of the slates. The air gaps 120 act as a low-dielectric constant medium to minimize capacitive coupling (e.g., from self heating effect) and preserve signal integrity at high frequencies. Such gaps are placed to optimize performance while maintaining structural stability. In an embodiment, the air gap 120 is proximate to an active device, e.g., below the top active device 110 or above the bottom active device 112.

Electrical connections between the first slate 102 to the second slate 104 are facilitated by an interconnect network comprising a plurality of conductive elements. An electrode 122 is on the first slate 102 to receive power or signals from an external node. In an embodiment, the electrode (or top electrode or top contact) 122 is made of aluminum. The top electrode 122 is electrically connected with a metal node 124 within the first semiconductor slate 102 via a plug 126, typically made of a highly conductive material such as tungsten or copper. The plug 126 provides low-resistance pathways for signal and power transmission between the vertically stacked layers.

A silicon structure 128 is proximate to the top active device 110 to mitigate self-heating effects by facilitating the dissipation of heat generated during device operation. In an embodiment, the silicon structure 128 is vertically aligned with the active device 110 (for example, is located above the active device) to dissipate heat generated by the active device. In an embodiment, the silicon structure is formed using a base silicon layer of the SOI substrate of the first slate 102 and is located directly on the buried oxide layer, as will be explained below. The silicon structure 128 may be referred to as a thermal dissipation structure, a thermal dissipation silicon structure, semiconductor thermal sink, semiconductor thermal structure or a silicon thermal structure.

Self-heating occurs when an active device generates heat during its operation. If the heat is not effectively dissipated, it can lead to self-heating effects that negatively impact the device's performance. This phenomenon is particularly common in 3D-integrated devices, such as 3D RF devices, where thermal management is challenging due to vertical stacking and the presence of insulating layers like buried oxide (BOX) layer. The resulting temperature increase from self-heating affects the device's electrical characteristics, including threshold voltage, carrier mobility, and overall performance.

In an embodiment, a single silicon structure (also referred to below as “silicon thermal structure”) 128 is respectively vertically aligned with each of the top active devices 110 for heat dissipation of the corresponding active device. The silicon thermal structure 128 should be of a sufficient size to effectively dissipate the heat generated by the active device 110. Accordingly, the size of the silicon thermal structure 128 may vary depending on the implementation. In an embodiment, the silicon thermal structure 128 has a lateral size approximately equal to that of the associated active device 110 (or active region). In another embodiment, the silicon thermal structure 128 may have a larger lateral size than the active device 110 (or active region). For example, the silicon thermal structure may be 15%, 30%, 45%, 60%, 75%, 100%, or 200% larger laterally than the active device 110 (or active region). Increasing the lateral size of the silicon thermal structure 128 compared to the size of an associated active device or active region enhances its heat dissipation capability. In another embodiment, a single silicon thermal structure 128 has sufficient lateral size to overlap with the two or more top active devices (or active regions) 108 to dissipate heat generated by these top active devices 108 (or active regions). Alternatively, a silicon thermal structure 128 may be smaller laterally than its corresponding active device 110, depending on the implementation.

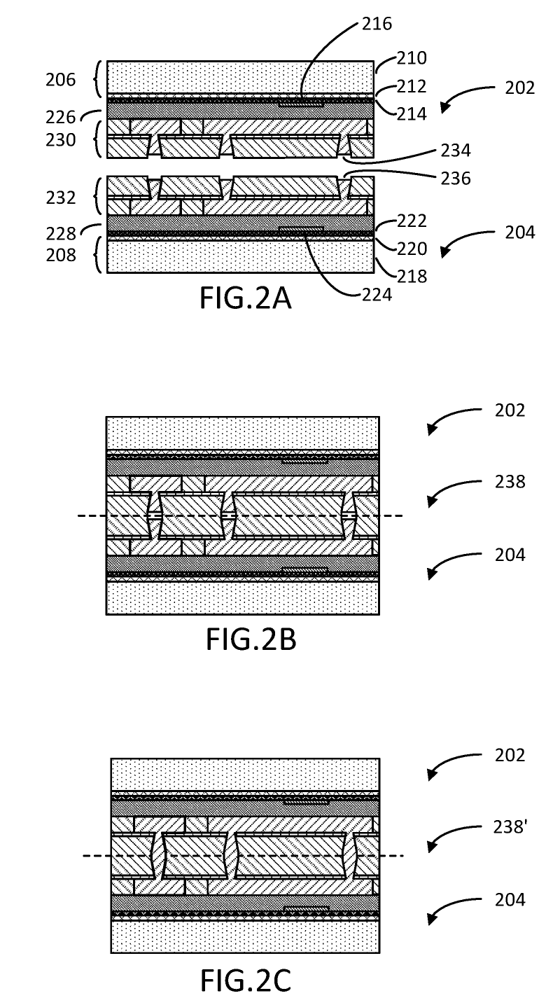

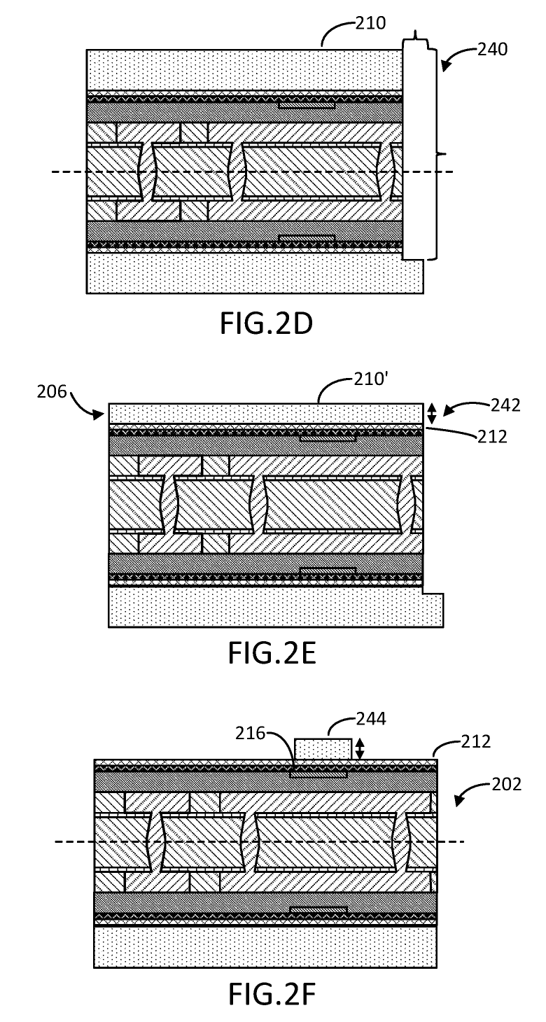

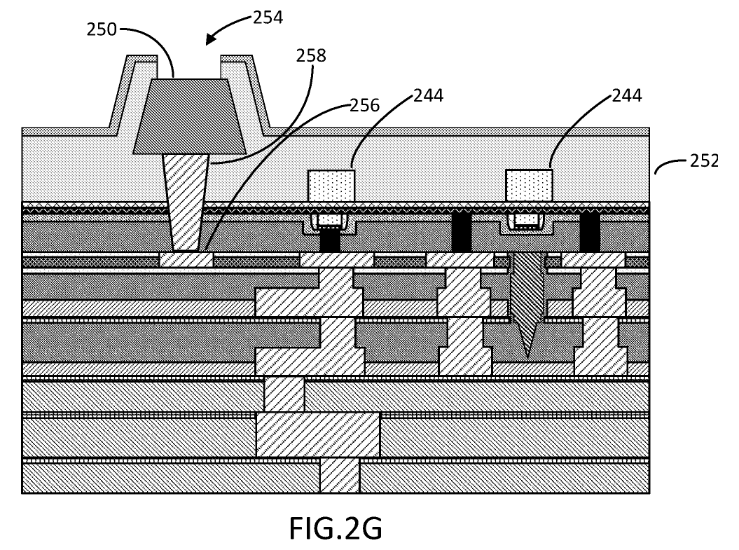

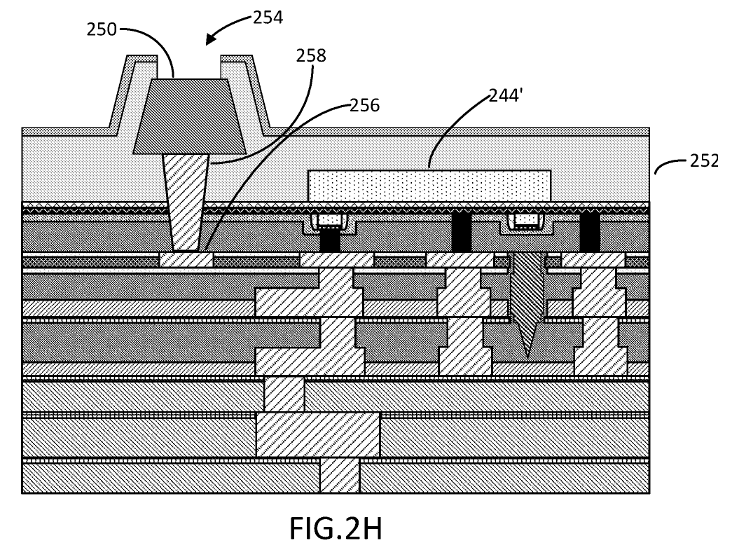

FIGS. 2A-2F illustrate a method for fabricating a three-dimensional (3D) semiconductor device (e.g., RF device) according to an embodiment of the present disclosure. A prebonding step is performed on a first semiconductor slate 202 and a second semiconductor slate 204 (FIG. 2A). In an embodiment, the first and second slates 202 and 204 include first and second silicon-on-insulator (SOI) substrates 206 and 208, respectively.

The first substrate (or the top substrate) 206 includes a base silicon layer 210 that provides structural stability and mechanical strength. The base silicon layer 210 may be also referred to as the base layer or handle substrate. In an embodiment, the base silicon layer 210 is made of silicon. In other embodiments, the base layer may be made of other semiconductor materials, e.g., germanium, silicon-germanium, or the like. A dielectric layer (e.g., buried oxide or BOX layer) 212 is provided on the base silicon layer 210. A semiconductor (e.g., silicon) layer 214 is positioned on the BOX layer 212. The BOX layer 212 serves as an insulating layer between the base silicon layer 210 and the silicon layer 214, providing electrical isolation between them and improving device performance. The first substrate 206 may be a partially-depleted SOI (PD-SOI) substrate, a fully-depleted SOI (FD-SOI) substrate, or ultra-thin body and BOX SOI, for example.

The silicon layer 214 may be also referred to as an active silicon layer because it serves as the functional region where active devices and circuits (or active regions) 216 are fabricated. The active devices 216 formed on the silicon layer 214 benefit from reduced parasitic capacitance, enhanced electrical isolation, and lower leakage currents, as the BOX layer 212 electrically isolates the active devices from the underlying base silicon layer 210.

The second substrate (or the bottom substrate) 208 is a SOI substrate similar to the first substrate 206, according to an embodiment of the present disclosure. The second SOI substrate 208 includes a base silicon layer 218, a BOX layer 220 and a silicon layer 222. A bottom active device (or active region) 224 is fabricated on the active silicon layer 218.

Each of the first and second slates 202 and 204 includes fabricated front-end-of-line (FEOL) layers 226, 228 and back-end-of-line (BEOL) layers 230, 232. A plurality of interconnects comprising metal structures 234 and 236 is formed in the BEOL layers.

The first substrate 206 and its FEOL and BEOL layers 226 and 230 define a top slate 202. The second substrate 208 and its FEOL and BEOL layers 228 and 232 define the bottom slate 204. As used herein, the term "slate" refers to a semiconductor substrate and a plurality of layers (e.g., FEOL and/or BEOL layers) formed on the substrate. In cases where a semiconductor substrate is an SOI substrate, "slate" may also refer to the SOI substrate and the layers formed on it, even if the base silicon layer is partially or completely removed.

Each of the top and bottom slates includes a plurality of dielectric layers and a plurality of metallization layers to enhance performance and integration. In an embodiment, the dielectric layers are formed using tetraethyl orthosilicate (TEOS).

Exposed dielectric layer and the metal (or via) structures on the top and the bottom slates serve as bonding surfaces. The bonding surfaces are planarized to obtain flat and smooth surfaces to minimize any topographic variations. In an embodiment, a chemical mechanical polishing (CMP) is used for the planarization step. The bonding surfaces are cleaned to remove particles, organic contaminants, or residues after the CMP step.

The top and bottom slates 202 and 204 are aligned to ensure proper stacking of their active devices, interconnects, and vias (FIG. 2B). The slates are brought into contact at room temperatures and the cleaned and pre-treated dielectric layers form a weak bond. These dielectric layers define a bonding fabric 238.

The slates 202 and 204 are annealed at an elevated temperature to strengthen the bond created by the bonding fabric 238 (FIG. 2C). The heat drives out any residual water and enhances atomic mobility at the interface that significantly increases the bonding strength of the bonding fabric 238’. In an embodiment, the elevated temperature used is at least 300 degrees Celsius (e.g., 800 degrees Celsius or higher). The bonding process may include oxide bonding and metal bonding. Alternatively, the bonding process may involve fusion bonding.

After annealing, the bonded slates (or a wafer stack) are trimmed along their edges (FIG. 2D). The edge-trimming process assists with uniformity and minimizes the risk of defects at the boundaries of the bonded wafer stack. In an embodiment, a column 240 approximately 3.2 mm in width and 806 µm in depth is removed from the edge of the wafer stack to ensure structural integrity and improve processing reliability.

The base silicon layer of the first substrate (or the top substrate) 206 is grinded to reduce its thickness to achieve the desired device dimensions (FIG. 2E). This grinding or thinning step is performed to enable high-density packaging and stacking of integrated circuits. In an embodiment, the base silicon layer 210’ is thinned to a thickness 242 of about 13 µm above the BOX layer 212. The base silicon layer 210’ may be thinner or thicker than 13 µm depending on implementations. For example, the base silicon layer 210’ may be thinned to about 10 µm if a thinner structure is desired or about 20 µm if a thicker structure is desired. In an embodiment, the desired thickness of the base silicon layer 210’ is influenced by the packaging density requirements of the 3D semiconductor device. In another embodiment, the desired thickness is determined, at least in part, by the requirements of the silicon thermal structure that will be formed in a subsequent step.

FIG. 2F illustrates forming a silicon structure (or a silicon thermal structure) 244 above the active device (or active region) 216 in the top slate 202 according to an embodiment of the present disclosure. A photoresist layer (not shown) is formed over the thinned base silicon layer. The photoresist layer is patterned, exposing selected areas of the thinned base silicon layer. The base silicon layer is etched using the patterned photoresist and the BOX layer 212 as an etch stop. A plurality of silicon thermal structure 244 is formed over the BOX layer 212. In an embodiment, the silicon thermal structures 244 are formed directly on the BOX layer 212. In another embodiment, an intervening layer may exist between the BOX layer 212 and the silicon thermal structures 244. For illustrative convenience only a single silicon thermal structure 244 is shown in FIG. 2F. In an embodiment, each of the silicon thermal structures is provided above an active device of the top slate. In an embodiment, the silicon thermal structure 244 has a thickness of about 5 µm to about 20 µm, from 10 µm to 15 µm, or for example, about 13 µm.

The silicon thermal structures 244 are used to improve the self heating effect, e.g., dissipate the heat generated by the active devices on the top slate during operation. The silicon thermal structure 244 may have a lateral size approximately equal to the active device (or active region) or may be significantly larger—such as 15%, 30%, 45%, 60%, 75%, 100%, or 200% larger—than the active device. Increasing the lateral size of the silicon thermal structure may increase heat dissipation capability. In another embodiment, a single silicon thermal structure is designed to have sufficient lateral size to overlap with the two or more top active devices to dissipate heat generated by these top active devices. Alternatively, a silicon thermal structure may be smaller laterally than its corresponding active device, depending on implementation.

In an embodiment, the thinned base silicon layer 210’ is left substantially intact to make a thermal structure. In other words, the photoresist is patterned to expose the areas where interconnects or vias will be formed while substantial portions of the base silicon layer 210’ remain covered by the patterned photoresist. The silicon etch step, therefore, generally removes the areas where interconnect and vias will be formed while leaving most of the thinned base silicon layer intact to serve as a large thermal structure for a plurality of active devices (or active regions) 216.

FIG. 2G illustrates forming a top electrode (or top contact) 250 according to an embodiment of the present disclosure. An upper surface of the top slate 202 is cleaned after the silicon etch step to remove any residues, contaminants, or damages caused by the silicon etch step. An insulating layer 252 is formed over a plurality of silicon thermal structures 244 that have been formed to facilitate the heat dissipation of the active devices. In an embodiment, the insulating layer 252 is deposited to a thickness of about 800 nm over the silicon thermal structures 244. A photoresist layer (not shown) is formed and patterned. A contact hole 254 is etched using the patterned photoresist. The contact hole 254 exposes a metal layer (e.g., a metal 1 layer) 256. A metal is deposited within the contact hole to form a contact plug 258. The top electrode 250 provides power or signals to the internal components of the 3D RF device via the contact plug 258. In an embodiment, the top electrode 250 is made of aluminum. An exemplary 3D RF device according to an embodiment is shown in FIG. 1. FIG. 2H illustrates a thermal structure 244’ for a plurality of active devices (or active regions) 216.

Embodiments of the present disclosure have numerous advantages over conventional 3D RF devices. The 3D-integrated RF device disclosed above delivers superior performance by incorporating an effective thermal management solution for the top active devices. The thermal sinks positioned over the top active devices facilitate efficient dissipation of heat generated during operation, ensuring stable device performance. Furthermore, the utilization of the base silicon layer of the top SOI substrate allows the thermal sinks to be integrated seamlessly, requiring minimal modifications to the existing fabrication process. This approach not only enhances thermal management but also maintains compatibility with established manufacturing workflows. These and other advantages will be apparent to a person of ordinary skill in art.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A semiconductor device, comprising:
a first slate including a first active device over a dielectric layer;
a second slate bonded to the first slate, the second slate including a substrate including a base semiconductor layer, a dielectric layer over the base semiconductor layer, and an active semiconductor layer over the dielectric layer; and
a first thermal structure over the first active device for dissipating heat generated by the first active device, the first thermal structure including a semiconductor material.

2. The semiconductor device of claim 1, wherein the semiconductor device is a three-dimensional (3D) RF device and the substrate of the second slate is a silicon-on-insulator (SOI) substrate and serves as a bottom substrate in the 3D RF device, and
wherein the first active device is over a first side of the dielectric layer and the first thermal structure is over a second side of the dielectric layer.

3. The semiconductor device of claim 2, wherein the dielectric layer is a buried oxide (BOX) layer of a silicon-on-insulator (SOI) substrate of the first slate, and the first thermal structure is directly on the BOX layer, the first and the second sides of the dielectric layer are on opposing sides of the dielectric layer.

4. The semiconductor device of claim 3, wherein the first thermal structure is a portion of a base silicon layer of the SOI substrate of the first slate.

5. The semiconductor device of claim 4, wherein the first thermal structure has a lateral size equal to or greater than that of the first active device.

6. The semiconductor device of claim 5, wherein the lateral size of the first thermal structure is at least about 50% larger than that of the first active device.

7. The semiconductor device of claim 1, further comprising:
a second active device over the dielectric layer; and
a second thermal structure over the second active device for dissipating heat generated by the second active device, the second thermal structure including a semiconductor material.

8. The semiconductor device of claim 7, wherein the dielectric layer is a buried oxide (BOX) layer of a silicon-on-insulator (SOI) substrate of the first slate, and the first and the second active devices are first and second top active devices, and
wherein the first thermal structure is directly on the BOX layer.

9. The semiconductor device of claim 8, wherein the first and the second thermal structures each include a portion of a base silicon layer of the SOI substrate.

10. The semiconductor device of claim 1, further comprising:
a second active device over the dielectric layer, the dielectric layer being a buried oxide (BOX) layer of a silicon-on-insulator (SOI) substrate of the first slate, and
wherein the first thermal structure is over the first and the second top active devices for dissipating heat generated by the first and the second top active devices, the first and second active devices being over a first side of the BOX layer and the first thermal structure being over a second side of the BOX layer.

11. The semiconductor device of claim 10, wherein the first thermal structure is directly on the BOX layer.

12. The semiconductor device of claim 11, wherein the first thermal structure is a portion of a base silicon layer of the SOI substrate.

13. The semiconductor device of claim 1, wherein the semiconductor device is a three-dimensional RF device, the semiconductor device further comprising:
an air gap below the first active device; and
a bonding fabric that joins the first and the second slates.

14. A three-dimensional integrated circuit (3DIC), comprising:
a bottom slate including a silicon-on-insulator (SOI) substrate and a bottom active device;
a top slate joined to the bottom slate and including a first top active device;
a dielectric layer over the first top active device; and
a first thermal structure over the first top active device for dissipating heat generated by the first top active device, the first thermal structure including a semiconductor material.

15. The 3DIC of claim 14, wherein the dielectric layer is a buried oxide (BOX) layer of a top SOI substrate of the top slate, and
wherein the first thermal structure is directly on the BOX layer.

16. The 3DIC of claim 15, wherein the first thermal structure is a portion of a base silicon layer of the top SOI substrate.

17. The 3DIC of claim 16, further comprising:
an air gap below the first top active device, and
a bonding fabric that joins the first and second slates,
wherein the 3DIC is a 3D RF device.

18. The 3DIC of claim 14, further comprising:
a second top active device; and
a second thermal structure over the second top active device for dissipating heat generated by the second top active device, the second thermal structure including a semiconductor material.

19. The 3DIC of claim 14, further comprising:
a second top active device,
wherein the dielectric layer is a buried oxide (BOX) layer, and
wherein the first thermal structure is over the first and second top active devices to dissipate heat generated by the first and the second top active devices, the first thermal structure being directly on the BOX layer.

20. A method for making a semiconductor device, the method comprising:
providing a bottom slate including a bottom silicon-on-insulator (SOI) substrate, the bottom SOI substrate including a bottom active device;
providing a top slate having a top SOI substrate including a top active device;
bonding the top slate and the bottom slate;
forming a semiconductor thermal structure using a base silicon layer of the top SOI substrate, the semiconductor thermal structure being configured to dissipate heat generated by the top active device;
forming a layer over the semiconductor thermal structure; and
forming a top electrode over the layer provided over the semiconductor thermal structure.
